(19) United States
(12) Patent Application Publication
(10) Pub. No.: US 2009/0327833 A1
(43) Pub. Date: Dec. 31, 2009

(54) MEMORY DEVICE

(75) Inventor: Hiroyuki Suto, Kawasaki (JP)

Correspondence Address: GREER, BURNS & CRAIN, 300 S WACKER DR, 25TH FLOOR, CHICAGO, IL, 60606, US

(73) Assignee: FUJITSU LIMITED, Kawasaki-shi (JP)

(21) Appl. No.: 12/475,160

(22) Filed: May 29, 2009

(30) Foreign Application Priority Data
Jun. 27, 2008 (JP) 2008-168970

(51) Int. Cl. H03M 13/05; G06F 11/10; G06F 11/07

(52) U.S. Cl. 714/752; 714/746; 714/E11.023; 714/E11.032

(57) ABSTRACT

A memory device includes: a data port for receiving data; a storing unit for storing data; a control signal input port for receiving a command signal; an error correcting unit for performing error correction operation over the data for the data port and the command signal for the control signal input port; and a control unit for controlling the storing unit for storing the data produced by the error correcting unit.

### CROSS-REFERENCE TO RELATED APPLICATION

This application is based upon and claims the benefit of priority of the prior Japanese Patent Application No. 2008-168970 filed on Jun. 27, 2008, the entire contents of which are incorporated herein by reference.

### FIELD

The embodiments discussed herein are related to a memory device for storing data.

### BACKGROUND

A volatile memory device that temporarily stores data and a non-volatile memory device are used for various applications. A Dynamic Random Access Memory (DRAM) is a typical volatile memory device including a Static Random Access Memory (SRAM). Further, a flash memory is a typical non-volatile memory device, including a Magneto-Resistive RAM (MRAM).

The memory device forms an information processing system in which data is subjected to transfer processing between the memory device and a memory controller such as a Central Processing Unit (CPU) and the data is stored to the memory device. Data transfer speed between the memory device and the memory controller increases year by year. The increase in data transfer speed enables the voltage magnitude of the data to be set to be small. The reduction in voltage magnitude enables the data to be transferred to be easily influenced from the electromagnetic noise. Therefore, the probability that the data written to the memory device becomes an error is high upon writing the data to the memory device from the memory controller.

When a data error occurs and if the memory device detects the error, the memory device may send a notification indicating the occurrence of the error to the memory controller. The memory controller that receives the notification indicating the occurrence of the error writes again the same data to the memory device, thereby storing correct data to the memory device. Japanese Laid-open Patent Publication Nos. 2001-14728A and 2002-351689A disclose a technology that a check circuit is provided between a data receiving device and a data bus and a parity bit is transferred together with the data to specify the occurrence position of the data error.

When the error is detected in the memory device, the memory controller writes again the same data to the memory device so as to store the correct data to the memory device. The memory controller may write the same data to the memory device again and again until the error is not notified from the memory device. The processing from the memory controller to the memory device results in increase in amount of written data. The increase in amount of written data causes the deterioration in data writing efficiency from the memory controller to the memory device.

### SUMMARY

According to an aspect of the embodiment, a memory device includes: a data port for receiving data; a storing unit for storing data; a control signal input port for receiving a command signal; an error correcting unit for performing error correction operation over the data for the data port and the command signal for the control signal input port; and a control unit for controlling the storing unit for storing the data produced by the error correcting unit.

The object and advantages of the embodiment will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating an information processing system for writing data to a memory device;

FIG. 2 is a diagram illustrating the information processing system for reading data from the memory device;

FIG. 3 is a block diagram illustrating the memory device;

FIG. 4 is a block diagram illustrating a memory controller;

FIG. 5 is a time chart indicating operation for writing data to the memory device;

FIG. 6 is a time chart indicating operation for writing data from the memory device;

FIG. 7 is a time chart of a command and an address to be transmitted to the memory device;

FIG. 8A is a table indicating contents of a command that sets an operational mode of a memory;

FIG. 8B is a table indicating contents of a command that sets an operational mode of a memory;

FIG. 8C is a table indicating contents of a command that sets an operational mode of a memory;

FIG. 8D is a table indicating contents of a command that sets an operational mode of a memory;

FIG. 8E is a table indicating contents of a command that sets an operational mode of a memory;

FIG. 8F is a table indicating contents of a command that sets an operational mode of a memory;

FIG. 9 is an operational flowchart of the memory device upon writing data to the memory device;

FIG. 10 is an operational flowchart of the memory device upon reading data from the memory device;

FIG. 11 is an operational flowchart of the memory controller upon writing data to the memory device; and

FIG. 12 is an operational flowchart of the memory controller upon reading data from the memory device.

### DESCRIPTION OF EMBODIMENTS

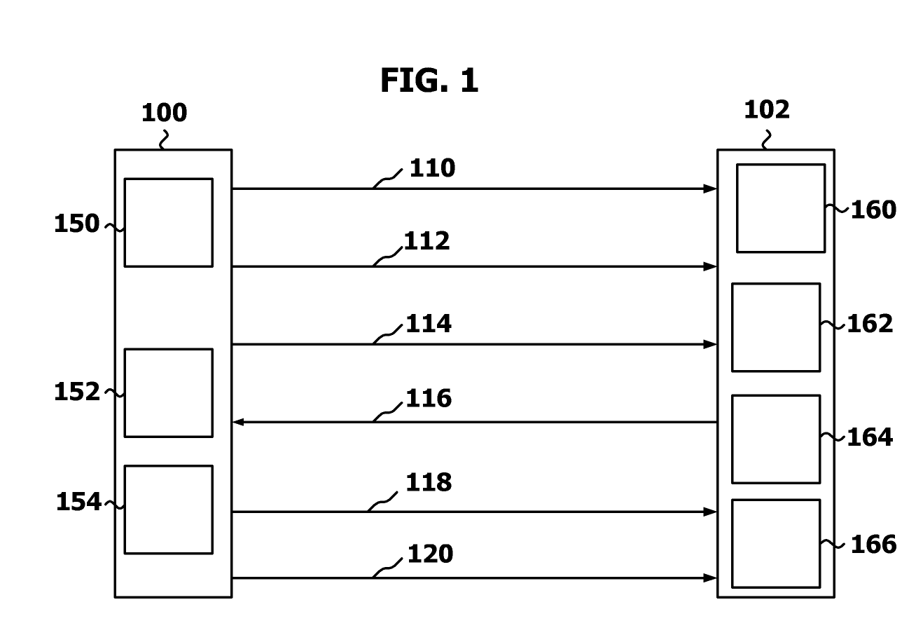

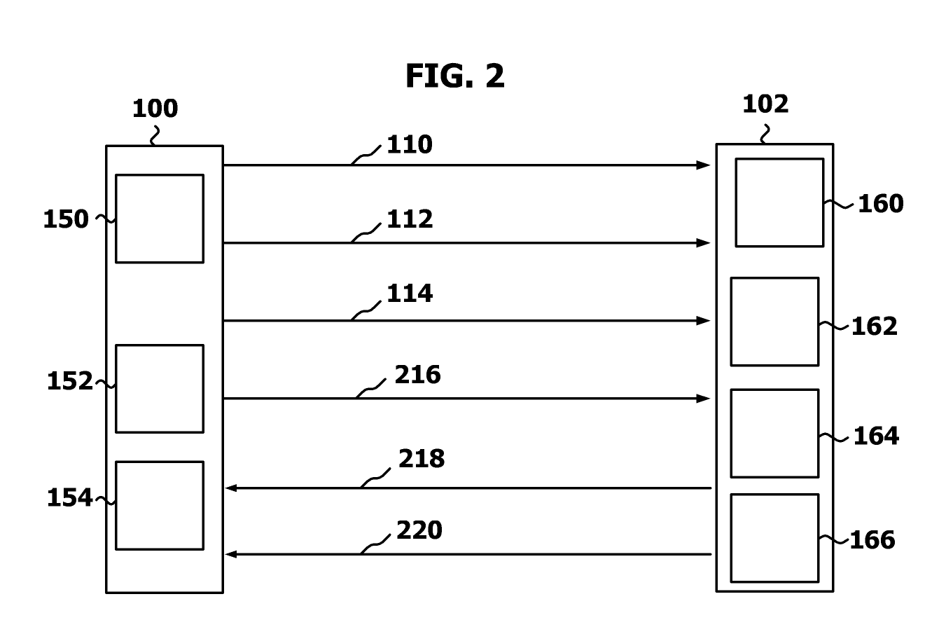

Hereinbelow, a description will be given of an information processing system according to the embodiment with reference to FIGS. 1 and 2.

FIG. 1 is a diagram illustrating the information processing system when a memory controller 100 writes data to a memory device 102. The memory controller 100 has a first control unit 150. The first control unit 150 controls operation for transmitting and receiving data to/from the memory controller 100. The memory device 102 has a second control unit 160. The second control unit 160 controls operation for transmitting and receiving data to/from the memory device 102. The first control unit 150 transmits a clock 110, a command signal 112, and an address signal 114 to the second control unit 160.

Herein, the memory device may be volatile memory and non-volatile memory. A Dynamic Random Access Memory (DRAM) is a typical volatile memory device, including a Static Random Access Memory (SRAM). Further, a flash memory is a typical non-volatile memory device, including a Magneto-resistive RAM (MRAM).

The first control unit 150 and the second control unit 160 are operated by the clock 110 respectively. With the command signal 112, the first control unit 150 sends a notification indicating information such as switching to operation for writing data and reading timing of the address signal 114 for designating an address for storing written data to the second control unit 160. With the address signal 114, the first control unit 150 sends a notification indicating address information for storing data to be written to the second control unit 160.

A first writing processing unit 154 in the memory controller 100 transmits data 118 and error correcting code (ECC) 120 created from the data 118 to a second writing processing unit 164 in the memory device 102. Herein, the ECC 120 is error correcting code for correcting an error of the data 118. The ECC 120 is used for error correcting processing of the data 118.

The second writing processing unit 164 performs the error correcting processing of the data 118 with the received ECC 120. After the error correcting processing, the second writing processing unit 164 may delete the received ECC 120. The second control unit 160 stores the data 118 after the error correcting processing to the notified address in a storing unit 166. When the error of the data 118 is not corrected in the error correcting processing, the second writing processing unit 164 sends a notification indicating the result of the process to the second control unit 160. The second control unit 160 issues an instruction for outputting an error notifying signal to the second writing processing unit 164 in the memory device 102.

The second writing processing unit 164 transmits an error notifying signal 116 to the first reading processing unit 152 in the memory controller 100. The first reading processing unit 152 sends a notification indicating that the error notifying signal 116 is received to the first control unit 150. The first control unit 150 sends a notification indicating that the data 118 is transmitted again to the first writing processing unit 154. The first writing processing unit 154 receives the notification from the first control unit 150, and transmits again the data 118 and the ECC 120 to the second writing processing unit 164.

According to the embodiment, upon writing data from the memory controller 100 to the memory device 102, the memory device 102 may correct an error of the data. Thus, the memory controller 100 may not write again and again the same data to the memory device 102 until the error is notified from the memory device 102. That is, the amount of written data from the memory controller 100 to the memory device 102 may be reduced. Accordingly, upon writing the data from the memory controller 100 to the memory device 102, the data writing efficiency may be improved. Further, the lifetime of the memory device 102 may be extended, and the data may be accurately written to the memory device 102.

As mentioned above, with the memory device 102, the error correcting processing realizes accurate writing of data to the memory device 102 without deteriorating a data transfer rate between the memory controller 100 and the memory device 102. Further, with the memory device 102, only the data 118 obtained by deleting the ECC 120 is stored to the storing unit 166, thereby enhancing a storage area of the data. Further, the ECC 120 may be stored to the storing unit 166 and the error correcting processing may be performed with the ECC 120 upon reading the data 118. With the stored ECC, the error of the data 118 in which the error occurs during storage in the storing unit 166 may be corrected.

FIG. 2 is a diagram illustrating the information processing system when the memory controller 100 reads data from the memory device 102. The first control unit 150 transmits the clock 110, the command signal 112, and the address signal 114 to the second control unit 160.

With the command signal 112, the first control unit 150 sends a notification indicating information such as switching to operation for reading the data and reading timing of the address signal 114 for designating an address for storing the read data to the second control unit 160. With the address signal 114, the first control unit 150 sends a notification indicating the address information for storing data to be read to the second control unit 160.

The second control unit 160 reads data 218 from the storing unit 166 on the basis of the address signal 114, and transmits the data to the second reading processing unit 162. The second reading processing unit 162 creates ECC 220 on the basis of the read data 218, and transmits the data 218 and the ECC 220 to the first reading processing unit 152 in the memory controller 100.

The first reading processing unit 152 performs the error correcting processing of the data 218 with the received ECC 220. The first reading processing unit 152 corrects the error, thereafter deletes the received ECC 220, and transfers only the data after correcting the error to an internal circuit in the memory controller 100.

When the error of the data 218 is not corrected in the error correcting processing, the first reading processing unit 152 sends such a fact to the first control unit 150. The first control unit 150 issues an instruction to output an error notifying signal to the first writing processing unit 154 in the memory controller 100.

The first writing processing unit 154 transmits an error notifying signal 216 to the second writing processing unit 164 in the memory device 102. The second writing processing unit 164 sends a notification indicating that the error notifying signal 216 is received to the second control unit 160. The second control unit 160 sends a notification indicating that the data 218 is transmitted again to the second reading processing unit 162. The second reading processing unit 162 receives the notification and transmits again the data 218 and the ECC 220 to the first reading processing unit 152.

As mentioned above, with the memory device 102, only the data is stored to the storing unit 166, and the ECC 220 is created and outputted upon reading the data. As a consequence, the storage area of data is enhanced, and reliability of the data read from the memory device 102 is improved. Further, with the memory device 102, the error correcting processing realizes accurate writing of data to the memory device 102 without reducing the data transfer rate between the memory controller 100 and the memory device 102.

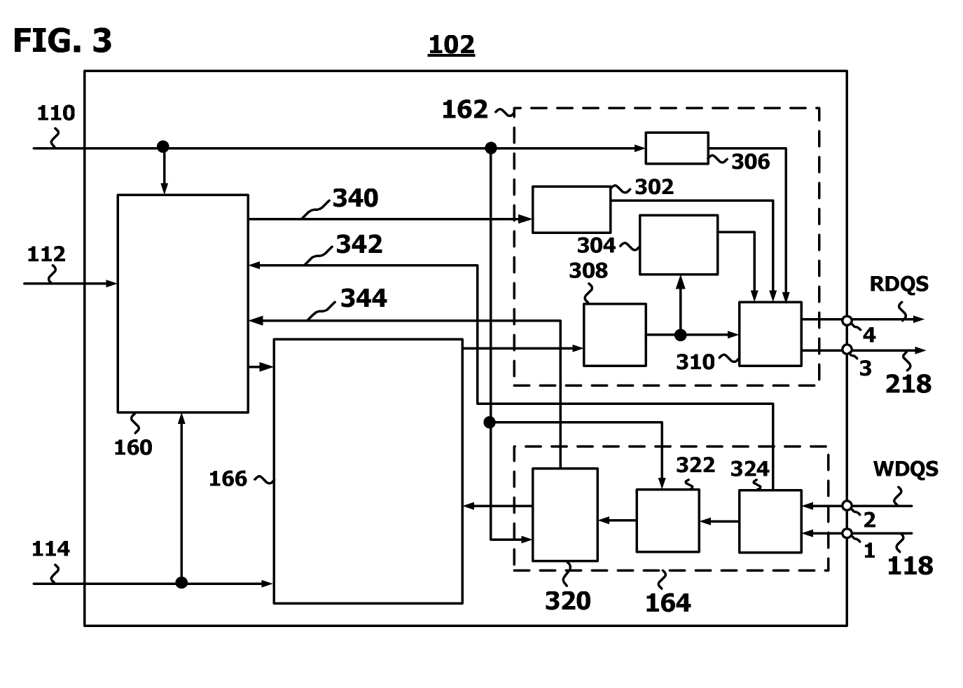

FIG. 3 is a specific block diagram illustrating the memory device 102. The memory device 102 comprises: the second control unit 160; the second reading processing unit 162; the second writing processing unit 164; and the storing unit 166.

Hereinbelow, a description will be given of the details of operation for writing data to the memory device 102. With the command signal 112, the second control unit 160 sets the memory device 102 to a data writing mode. The second control unit 160 sets a writable state of the address of the storing unit 166 designated by the address signal 114.

The second writing processing unit 164 comprises: a receiving unit 324; a First-In First-Out (FIFO) 322; and an error correcting unit 320. The FIFO is one type of buffers, and outputs data inputted to the FIFO in older order at the timing of the clock 110. The receiving unit 324 receives the data 118 and a write data strobe signal (Write DQS: WDQS). The data 118 is inputted to a terminal 1 and the WDQS is inputted to a terminal 2. The terminal 1 functions as a data port for receiving data. The terminal 2 functions as a control signal input port for receiving an input. The WDQS is received together with the data upon writing the data 118, and is used as a data strobe signal that adjusts the timing for capturing the data 118. Since the data strobe signal is not required at the timing at which the data 118 is not received, an output of the WDQS in the memory controller 100 is generally fixed to high impedance.

The receiving unit 324 receives an operation notifying signal with the WDQS before receiving the data 118. The operation notifying signal sets the error correcting processing in the error correcting unit 320 to be effective. The receiving unit 324 sends, with a request signal 342, a notification indicating that the operation notifying signal is received to the second control unit 160. In response to the request signal 342, the second control unit 160 sets the error correcting unit 320 to enter an ECC check operating mode. Further, as will be described later, the ECC operation may be invalid upon turning on the memory device 102. Even in the operating mode, the operation notifying signal is received, thereby temporarily setting the ECC processing to be effective. Accordingly, when one specific piece of data is written to the memory device 102, the reliability of the data may be improved.

The receiving unit 324 reads the data 118 synchronously with the data strobe signal transmitted in response to the WDQS. According to the embodiment, a burst length as a specific bit-length of the data 118 is 8 bits, but the burst length may be another length. After ending the reception of the data 118 and predetermined time passes, the receiving unit 324 receives the ECC 120 with the WDQS. Time from the end of receiving the data 118 to the reception of the ECC 120 is set by the command signal 112 and the address signal 114, as will be described later. Accordingly, the receiving unit 324 may receive the ECC 120.

The WDQS received by the receiving unit 324 is transmitted by a difference wiring. The difference wiring is used for transmitting a difference signal. Since the difference signal is not easily influenced from external noise such as electromagnetic noise, the difference signal has an error occurrence rate lower than the error occurrence rate of the data 118. The memory controller 100 transmits the ECC 120 with the WDQS, thereby protecting the ECC 120 from the external noise. Accordingly, the memory device 102 may improve the accuracy of the error correction. Further, unlike the difference wiring for transmitting the WDQS, with the difference wiring for propagating a signal with the error occurrence rate lower than that of a wiring for transmitting the data 118, the ECC 120 may be transmitted from the memory controller 100 to the memory device 102. In this case, the memory controller 100 may transmit simultaneously the ECC 120 together with the data 118 to the memory device, independently of the presence or absence of the data strobe signal. Thus, the data writing efficiency to the memory device 102 may be further improved.

The receiving unit 324 transmits the received data 118 and ECC 120 to the FIFO 322. The FIFO 322 transmits the data 118 and ECC 120 to the error correcting unit 320 synchronously with the clock 110.

The error correcting unit 320 temporarily stores the received data 118 and ECC 120. The error correcting unit 320 creates reference error correcting code from the temporarily stored data 118. The error correcting unit 320 compares the reference error correcting code with the ECC 120. If the reference error correcting code matches the ECC 120 as a comparing result, the error correcting unit 320 may determine that the data 118 does not have the error. If the error correcting code for reference does not match the ECC 120 as the comparing result, the error correcting unit 320 may determine that the data 118 has the error. When it is determined that the data 118 has the error, the error correcting unit 320 performs the error correcting processing of the data 118 with the ECC 120.

When the error correcting processing is successful, the error correcting unit 320 transmits the data 118 after correcting the error to the storing unit 166. The memory device 102 realizes accurate writing of data to the memory device 102 with the error correcting processing without deteriorating the data transfer rate between the memory controller 100 and the memory device 102.

When the error correcting processing fails, the error correcting unit 320 sends a notification for indicating the failure to the second control unit 160 with an error detecting signal 344. The second control unit 160 transmits a creating signal 340 to a read data strobe signal (Read DQS: RDQS) creating unit 302 to the memory controller 100 so as to send a notification indicating that the error is not corrected. In response to the creating signal 340, the RDQS creating unit 302 creates the error notifying signal 116 and the created signal to a transmitting unit 310. The transmitting unit 310 transmits the error notifying signal 116 to the memory controller 100 with the RDQS. The memory controller 100 that receives the error notifying signal 116 transmits again the data 118 to the memory device 102. As a consequence, normal data 118 may be stored to the memory device 102.

The number of error bits of data 118 of possible error correction increases by increasing the number of bits of ECC 120. However, time for transmitting the ECC 120 from the memory controller 100 to the memory device 102 is longer. According to the embodiment, the ECC 120 has 2 bits. Since the bit length of the data 118 is 8 bits as mentioned above, the ECC 120 with 2 bits enables the error detection with the error detection with 1 bit or 2 bits.

After ending the error correcting processing, the second control unit 160 may delete the ECC 120 that is temporarily stored in the error correcting unit 320 and may store only the data 118 to the storing unit 166. The storage of only the data 118 to the storing unit 166 enables the memory device 102 to store a large amount of data as compared with the case of storing the data together with the ECC 120. Further, after ending the error correcting processing, the ECC 120 may be stored to the storing unit 166 together with the data 118. The error occurring in the data 118 during storing the storing unit 166 is corrected by using the ECC 120 stored upon reading the data 118. As a consequence, the reliability of the data 118 may be further improved.

Hereinbelow, a specific description will be given of operation for reading data to the memory device 102. The second control unit 160 sets the memory device 102 to a data reading mode on the basis of the command signal 112. The second control unit 160 sets the address of the storing unit 166 designated by the address signal 114 to be readable.

The second reading processing unit 162 comprises: the transmitting unit 310; a bus-width adjusting unit 308; a code creating unit 304; an RDQS creating unit 302; and a Delay Locked Loop (DLL) 306. The DLL adjusts the synchronization between the clock 110 and the data 218 outputted from the transmitting unit 310.

The transmitting unit 310 outputs the data 218 and a read data strobe signal (Read DQS: RDQS). The data 218 is outputted from a terminal 3 and the RDQS is outputted from a terminal 4. The RDQS is transmitted together with the data 218 upon reading the data 218, and is used as a data strobe signal that adjusts the timing for capturing the data 218 by the memory controller 100. At the timing at which the data 218 is not transmitted, the data strobe signal is not required. Therefore, an output of the RDQS in the memory device 102 is usually fixed to high impedance.

The second control unit 160 transmits the creating signal 340 to the RDQS creating unit 302 upon transmitting the ECC 220 together with the data 218 to the memory controller 100. The RDQS creating unit 302 creates the operation notifying signal and transmits the created signal to the transmitting unit 310. The transmitting unit 310 transmits the operation notifying signal as the RDQS to the memory controller 100.

The RDQS is transmitted by the difference wiring. The difference wiring is not easily influenced from external noise such as electromagnetic noise. The memory device 102 transmits the ECC 220 as the RDQS, thereby improving the reliability of the ECC 220. Accordingly, the memory controller 100 may improve the accuracy of the error correction. Unlike the difference wiring that transmits the WDQS, the ECC 120 may be transmitted from the memory controller 100 to the memory device 102 with a wiring having an error occurrence rate lower than that of a wiring for transmitting the data 118. The memory controller 100 may simultaneously transmit the ECC 120 together with the data 118 to the memory device, irrespective of the absence or presence of the data strobe signal. Accordingly, the data writing efficiency to the memory device 102 may be improved.

The bus-width adjusting unit 308 has a latch circuit and a multiplexer, and adjusts the data 218 read from the storing unit 166 to a preset bus width of data. The bus-width adjusting unit 308 transmits the data 218 to the transmitting unit 310 and the code creating unit 304. The code creating unit 304 creates the ECC 220 on the basis of the data 218 and transmits the created ECC 220 to the transmitting unit 310. The transmitting unit 310 transmits the data 218 and the ECC 220 to the memory controller 100.

When the error correcting processing fails, the memory controller 100 may issue again a request for transmitting the same data to the memory device 102. Accordingly, the memory controller 100 may increase the possibility for reading normal data from the memory device 102.

As mentioned above, upon writing the data from the memory controller 100 to the memory device 102, the error of the data may be corrected in the memory device 102. The memory controller 100 may not write the same data to the memory device 102 again and again until the error notification is not received from the memory device 102. That is, the amount of written data from the memory controller 100 to the memory device 102 may be reduced. Accordingly, upon writing the data from the memory controller 100 to the memory device 102, the data writing efficiency may be improved. Further, the lifetime of the memory device 102 is prolonged, thereby realizing accurate writing of data to the memory device 102.

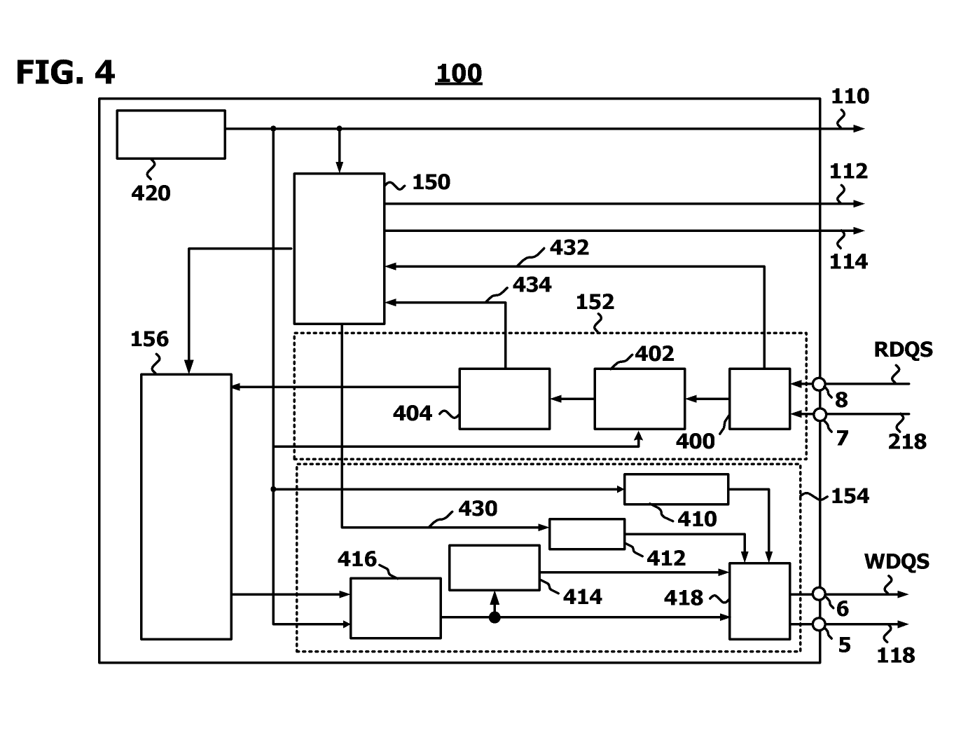

FIG. 4 is a specific block diagram illustrating the memory controller 100. The memory controller 100 comprises: the first control unit 150; the first reading processing unit 152; the first writing processing unit 154; and an internal circuit 156. A clock creating unit 420 creates the clock 110. The clock 110 may be supplied externally from the memory controller 100.

Hereinbelow, a description will be given of the details of operation for writing the data to the memory device 102. The first control unit 150 transmits the command signal 112 and sets the memory device 102 to a data writing mode. The first control unit 150 designates an address for writing the data 118 with the address signal 114.

The first writing processing unit 154 comprises: a transmitting unit 418; an FIFO 416; a code creating unit 414; a WDQS creating unit 412; and a DLL 410. The transmitting unit 418 outputs the data 118 and the WDQS.

Before transmitting the data 118, the memory controller 100 transmits the operation notifying signal with the WDQS. The data 118 is outputted from a terminal 5 and the WDQS is outputted from a terminal 6. The first control unit 150 transmits a creating signal 430 to the WDQS 412. The WDQS creating unit 412 creates the operation notifying signal and transmits the created signal to the transmitting unit 418. The transmitting unit 418 transmits the operation notifying signal as the WDQS to the memory device 102.

After transmitting the operation notifying signal, the first writing processing unit 154 transmits the ECC 120 and the data 118 to the memory device 102. In the first writing processing unit 154, the FIFO 416 synchronizes the timing of the data 118 transmitted from the internal circuit 156 with the clock 110, and transmits the signal to the transmitting unit 418. The code creating unit 414 creates the ECC 120 from the data 118 and transmits the created ECC 120 to the transmitting unit 418. The transmitting unit 418 transmits the data 118 and the ECC 120 to the memory device 102 in accordance with the timing whose phase is adjusted by the DLL 410.

When the error correcting processing of the data 118 fails, the memory device 102 transmits the error notifying signal 116 to a receiving unit 400. The receiving unit 400 transmits a request signal 432 to the first control unit 150. The first control unit 150 receives the request signal 432 and then issues a request for transmitting again the same data 118 to the internal circuit 156. The memory device 102 receives again the same the data 118, thereby storing the correct data 118.

Hereinbelow, a specific description will be given of operation for reading data from the memory device 102. The first control unit 150 transmits the command signal 112 and sets the memory device 102 to a data reading mode. Further, the first control unit 150 designates the data 218 as a reading target with the address signal 114.

The first reading processing unit 152 comprises: the receiving unit 400; an FIFO 402; and an error correcting unit 404. The receiving unit 400 receives the data 218 and the RDQS. The data 218 is inputted to a terminal 7 and the RDQS is inputted to a terminal 8.

The receiving unit 400 sends a notification indicating that the operation notifying signal is received to the first control unit 150. The first control unit 150 sets the error correcting unit 404 to an ECC check operating mode.

The receiving unit 400 reads the data 218 synchronously with the data strobe signal transmitted with the RDQS. After the reception of the data 218 ends and predetermined time passes, the receiving unit 400 receives the ECC 220 with the WDQS. Time from the end of reception of the data 218 to the reception of the ECC 220 is set by the command signal 112 and the address signal 114, which will be described later. Accordingly, the receiving unit 400 may receive the ECC 120. Further, the RDQS is transmitted by a difference wiring. The difference wiring is not easily influenced from external noise such as electromagnetic noise. The ECC 220 is transmitted with the RDQS, thereby protecting the ECC 220 from the external noise. Accordingly, the memory controller 100 may improve the accuracy for correcting the error.

The receiving unit 400 transmits the received data 218 and ECC 220 to the FIFO 402. The FIFO 402 transmits the data 218 and the ECC 220 to the error correcting unit 404 synchronously with the clock 110. The error correcting unit 404 corrects the error of the data 218 with the received ECC 220. According to the embodiment, the ECC 220 has 2 bits. The bit length of the data 218 is 8 bits as mentioned above and the error correcting unit 404 may therefore correct the error having 1 bit with the ECC 220 having 2 bits and may also detect the error having 2 bits.

When the error correcting processing is successful, the error correcting unit 404 transmits the data 218 after the error correction to the internal circuit 156. After ending the error correcting processing, the ECC 220 may be deleted.

When the error correcting processing fails, the error correcting unit 404 sends a notification indicating the failure to the first control unit 150 with an error detecting signal 434. The first control unit 150 transmits the creating signal 430 to the WDQS creating unit 412 so as to send a notification indicating that the error is not corrected to the memory device 102. The WDQS creating unit 412 creates the error notifying signal 216 in response to the creating signal 430, and transmits the created signal to the transmitting unit 418. The transmitting unit 418 transmits the error notifying signal 216 to the memory device 102 with the WDQS. The memory device 102 that receives the error notifying signal 216 transmits again the data 218 to the memory controller 100. Accordingly, the memory device 102 may increase the probability for receiving the normal data 218 by the memory controller 100.

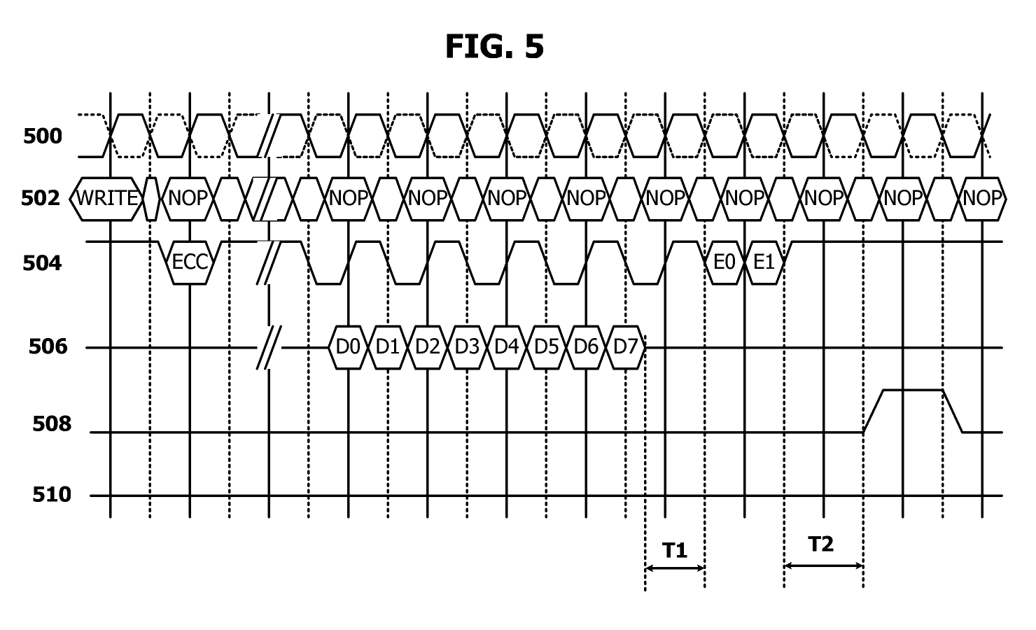

FIG. 5 is a time chart upon writing data from the memory controller 100 to the memory device 102. A waveform 500 denotes the clock 110. A waveform 502 denotes the command signal 112. With the waveform 502, a ‘WRITE’ command sets the memory device 102 to a data writing allowable mode. A waveform 504 denotes the WDQS. With the waveform 504, an ‘ECC’ signal is the operation notifying signal transmitted from the memory controller 100 to the memory device 102.

With a waveform 506, D0 to D7 denote the data 118 with 8 bits written to the memory device 102. After time T1 passes from the reception end of the data 118, the memory device 102 receives E0 and E1. The E0 and E1 are the ECC 120 as the error correcting code of the data 118.

A waveform 508 denotes the RDQS upon detecting the error in the memory device 102. With the waveform 508, a pulse waveform after time T2 from the reception of the ECC is the error notifying signal 116. On the other hand, a waveform 510 denotes the RDQS when the error is not detected in the memory device 102. When the error is not detected, as shown by the waveform 510, a pulse waveform is not generated after the time T2 from the ECC reception.

The times T1 and T2 are set to the memory device 102 by the command signal 112 and the address signal 114 transmitted from the memory controller 100 to the memory device 102 upon starting the memory controller 100. Accordingly, the memory device 102 may obtain the ECC 120 with the WDQS, and the memory controller 100 may obtain the error notifying signal 116 with the RDQS. A setting method of the times T1 and T2 will be described later.

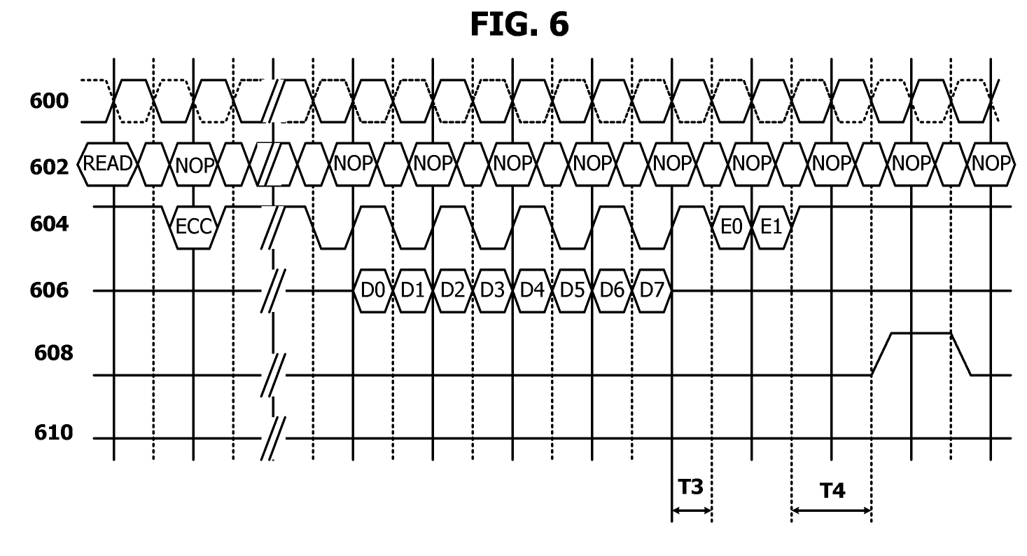

FIG. 6 is a time chart upon reading data from the memory device 102 by the memory controller 100. A waveform 600 denotes the clock 110. A waveform 602 denotes the command signal 112. With the waveform 602, a ‘READ’ command sets the memory device 102 to a data reading allowable mode. A waveform 604 denotes the RDQS. With the waveform 604, an ‘ECC’ signal is the operation notifying signal transmitted from the memory device 102 to the memory controller 100.

With a waveform 606, D0 to D7 are the data 218 having 8 bits read from the memory device 102. After time T3 from the transmission end of the data 218, the memory device 102 transmits E0 and E1. The E0 and E1 are the ECC 220 as the error correcting code of the data 218.

A waveform 608 denotes the WDQS when the error is detected by the memory controller 100. With the waveform 608, a pulse waveform after time T4 from the transmission of the ECC 220 is the error notifying signal 216. On the other hand, a waveform 610 denotes the RDQS when the error is not detected by the memory controller 100. When the error is not detected, as shown by the waveform 610, a pulse waveform is not generated after the time T4 from the transmission of the ECC 220.

The times T3 and T4 are set to the memory device 102 by the command signal 112 and the address signal 114 transmitted from the memory controller 100 to the memory device 102 upon starting the memory controller 100. Accordingly, the memory controller 100 may obtain the ECC 220 with the RDQS, and the memory device 102 may obtain the error notifying signal 216 with the WDQS. A setting method of the times T3 and T4 will be described later.

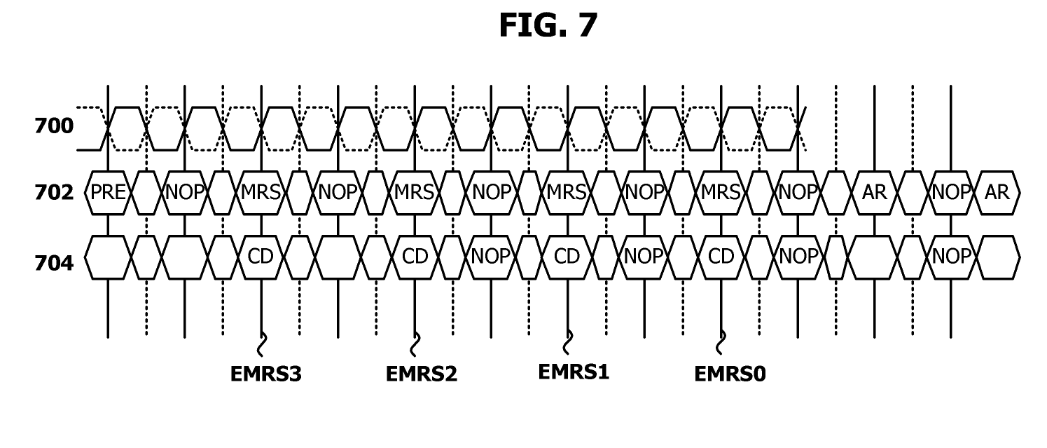

FIG. 7 is a time chart of the command signal 112 and the address signal 114 transmitted from the memory controller 100 to the memory device 102 upon setting the times T1, T2, T3, and T4.

A waveform 700 denotes the clock 110. A waveform 702 denotes a command signal 112. With the waveform 702, an ‘MRS’ command sets the operation mode of the memory device 102. Depending on contents of a bit string of the ‘MRS’ command, the type of the operation mode set to the memory device 102 is varied. According to the embodiment, in response to the ‘MRS’ command, an EMRS3 mode is set.

A waveform 704 denotes the address signal 114. With the waveform 704, a ‘CD’ command denotes a bit string corresponding to the operation mode set in response to the ‘MRS’ command. Depending on the arrangement of the bit string, the length of the times T1 to T4 may be set.

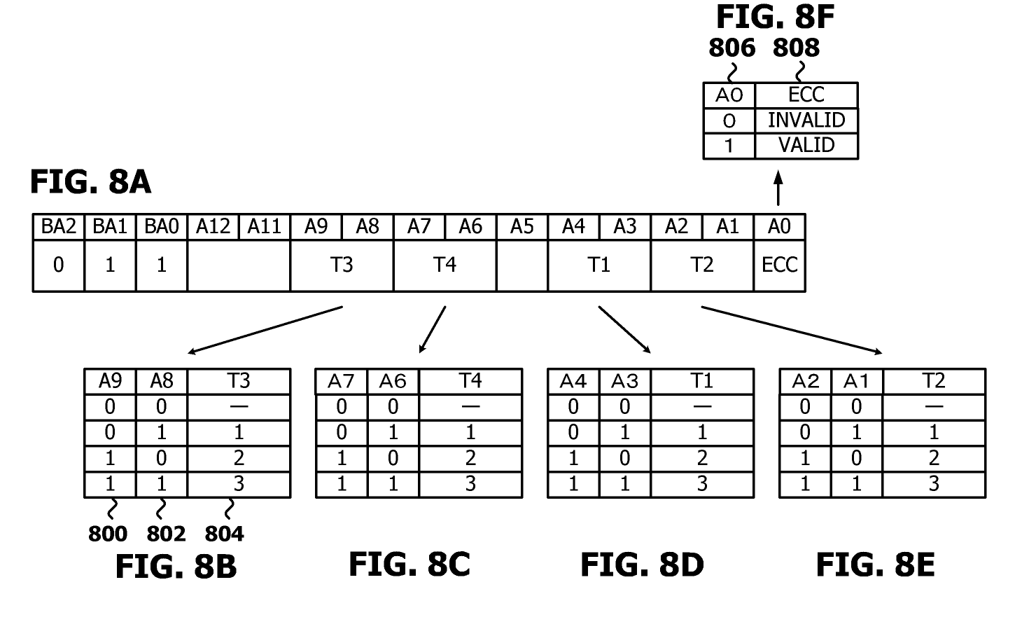

FIG. 8A to FIG. 8F are tables indicating contents of a command for setting the operation mode. Referring to FIG. 8A denotes the ‘MRS’ command and the ‘CD’ command. Reference numerals BA0 to BA2 denote bit strings of the ‘MRS’ command. Reference numerals A0 to A12 denote bit strings of the ‘CD’ command. In the ‘CD’ command, the bit strings A9 and A8 determine the length of the time T3. The bit strings A7 and A6 determine the length of the time T4. The bit strings A4 and A3 determine the length of the time T1. The bit strings A2 and A1 determine the length of the time T2. FIG. 8B denotes a table illustrating a relationship between values of A9 and A8 and the length of the time T3. FIG. 8C denotes a table illustrating a relationship between values of A7 and A6 and the length of the time T4. FIG. 8D denotes a table illustrating a relationship between values of A4 and A3 and the length of the time T1. FIG. 8E denotes a table illustrating a relationship between values of A2 and A1 and the length of the time T2. Since the formats of FIG. 8B to FIG. 8E are the same, only FIG. 8B will be described in details and other tables will not be described.

With FIG. 8B, a column 800 denotes a value of A9. A column 802 denotes a value of A8. A column 804 denotes the length of the time T3 determined depending on the values of A9 and A8. The length of time is indicated by the number of the clocks 110. When the value of A9 is set to ‘0’ in the column 800 and the value of A8 is set to ‘1’ in the column 802, the length of the time T3 corresponds to 1, i.e., the length of one period of the clock. Similarly, the lengths of the times T4, T1, and T2 may be set on the basis of FIG. 8C, FIG. 8D, and FIG. 8E.

With FIG. 8F, a column 806 denotes a value of A0. A column 808 denotes the operation mode of the memory device 102 corresponding to the value of A0. When A0 is ‘0’, the memory device 102 performs data writing processing by assuming that the ECC is invalid, i.e., the ECC data corresponding to the written data does not exist. When A0 is ‘1’, the memory device 102 performs the data writing processing by assuming that the ECC is valid, i.e., the ECC data corresponding to the written data exists. The operation mode of the memory device 102 may be set depending on A0 upon turning-on the power, and the operation notifying signal to be transmitted to the memory with the WDQS 504 may not be required. Accordingly, the data writing speed to the memory device 102 may be improved.

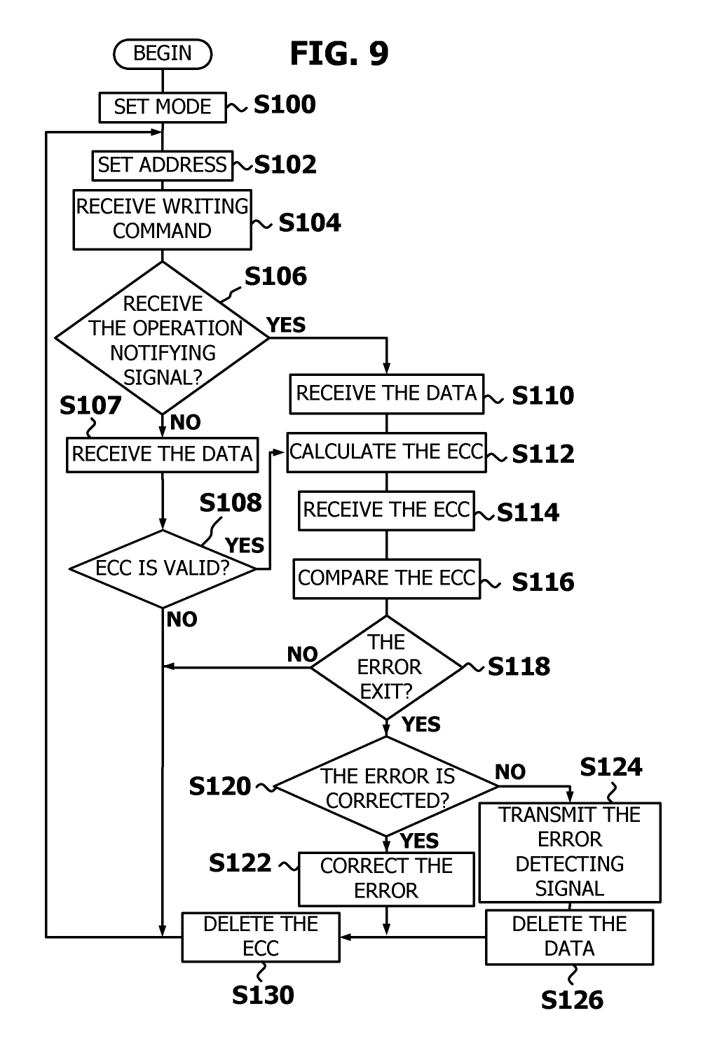

FIG. 9 is an operational flowchart of the memory device 102 in the data writing processing from the memory controller 100 to the memory device 102. The power is turned on and the second control unit 160 in the memory device 102 then sets an operation mode for determining whether or not the ECC processing is valid in response to the command signal 112 received from the memory controller 100 (in step S100). The second control unit 160 sets a specific address of the storing unit 166 to an accessible mode with the address signal 114 received from the memory controller 100 (in step S102). The second control unit 160 receives a writing command with the command signal 112 and then sets the storing unit 166 to a writing mode (in step S104).

When the receiving unit 324 receives the operation notifying signal (YES in step S106), the receiving unit 324 receives the data and transmits the request signal 342 indicating that the ECC processing is performed to the second control unit 160 (in step S110). The error correcting unit 320 calculates the ECC on the basis of the received data (in step S112). Further, the receiving unit 324 receives the ECC data, and transmits the received ECC data to the error correcting unit 320 (in step S114). The error correcting unit 320 compares the received ECC with the ECC created on the basis of the received data, and performs the error detecting processing (in step S116).

When the error exists as a result of the error detecting processing (YES in step S118), when the error may be corrected (YES in step S120) the error correcting unit 320 performs the error correcting processing of data, and transmits data after the error correction to the storing unit 166 (in step S122). After correcting the error, the error correcting unit 320 deletes the ECC (in step S130). The second control unit 160 enters a standby mode until receiving the next command signal 112 and address signal 114. In step S130, the error correcting unit 320 may not delete the ECC and may transmit the ECC and the data to the storing unit 166.

When the error exists as a result of the error detecting processing (YES in step S118), when the error may not be corrected (NO in step S120) the error correcting unit 320 transmits the error detecting signal to the second control unit 160 (in step S124). The second control unit 160 transmits the creating signal 340 to the RDQS creating unit 302. The RDQS creating unit 302 transmits the error notifying signal to the transmitting unit 310. The transmitting unit 310 transmits the error notifying signal to the memory controller 100 with the RDQS signal. The error correcting unit 320 deletes the data whose error may not be corrected (in step S126). Further, the error correcting unit 320 deletes the received ECC (in step S130).

When the error does not exist as a result of the error detecting processing (NO in step S118), the error correcting unit 320 deletes the ECC and transmits the data to the storing unit 166 (in step S130).

When the operation notifying signal is not received (NO in step S106), the receiving unit 324 receives the data (in step S107). When the ECC processing is valid in the setting of the operation mode (YES in step S108), the error correcting unit 320 calculates the ECC (in step S112). The ECC processing is valid upon setting the operation mode of the memory device 102, and the error correcting unit 320 may consequently perform the ECC processing, irrespective of the operation notifying signal. Accordingly, the operation notifying signal is not required, and the data writing processing speed may be improved. Further, even if the ECC processing is invalid upon setting the operation mode, the operation notifying signal is used, thereby executing the ECC processing of only specific data. When the ECC processing is invalid upon setting the operation mode (NO in step S108), the error correcting unit 320 transmits the received data to the storing unit 166 without the ECC processing.

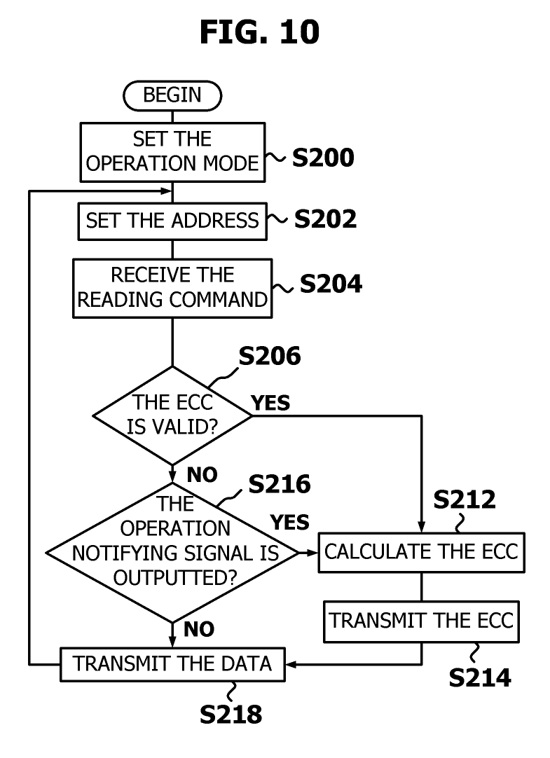

FIG. 10 is a flowchart for explaining processing of the memory device 102 when the memory controller 100 reads the data from the memory device 102. The power is turned on and the second control unit 160 in the memory device 102 then sets the operation mode for determining whether or not the ECC processing is valid in response to the command signal 112 received from the memory controller 100 (in step S200). The second control unit 160 sets a specific address of the storing unit 166 to an accessible mode with the address signal 114 received from the memory controller 100 (in step S202). The second control unit 160 receives a reading command in response to the command signal 112 and then sets the storing unit 166 to a reading mode (in step S204).

When the ECC processing is valid upon setting the operation mode (YES in step S206), the code creating unit 304 calculates the ECC on the basis of data that is read from the storing unit 166 and is then outputted from the bus-width adjusting unit 308 (in step S212). The transmitting unit 310 transmits the created ECC 220 to the memory controller 100 (in step S214). Further, the transmitting unit 310 transmits the data 218 to the memory controller 100 (in step S218). When the data and the ECC are stored in the storing unit 166 upon writing the data, the code creating unit 304 may also perform the error correcting processing of the read data by using the ECC stored in the storing unit 166 (in step S212).

Even when the ECC processing is invalid upon setting the operation mode (NO in step S206) and when the operation notifying signal is to be outputted (YES in step S216), the second control unit 160 transmits the creating signal 340 to the RDQS creating unit 302. Further, the code creating unit 304 calculates the ECC 220 (in step S212), and also transmits the ECC 220 to the memory controller 100 (in step S214). The transmitting unit 310 transmits the created ECC 220 to the memory controller 100 (in step S214). Further, the transmitting unit 310 transmits the data 218 to the memory controller 100 (in step S218). When the operation notifying signal is not outputted (NO in step S216), the transmitting unit 310 transmits the data 218 received from the storing unit 166 to the memory controller 100 (in step S218).

The ECC processing is valid upon setting the operation mode of the memory device 102, thereby enabling the ECC processing independently on the operation notifying signal. Accordingly, the operation notifying signal is not required and the data reading processing speed may be improved. Further, even if the ECC processing is invalid upon setting the operation mode, the operation notifying signal is outputted, thereby executing the ECC processing of only specific data by the memory controller 100.

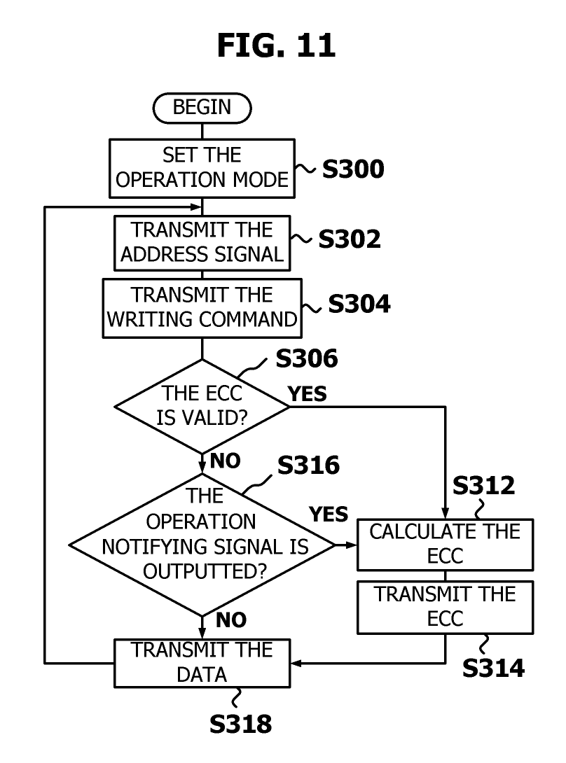

FIG. 11 is an operational flowchart of the memory controller 100 for explaining the data writing processing from the memory controller 100 to the memory device 102. The first control unit 150 in the memory controller 100 transmits the command signal 112 for setting the operation mode indicating whether or not the ECC processing is valid to the memory device 102 (in step S300). The first control unit 150 transmits the address signal 114 that designates an address for writing the data to the memory device 102 (in step S302). The first control unit 150 transmits a writing command to the memory device 102 in response to the command signal 112 and sets the memory device 102 to a writing mode (in step S304).

When the ECC processing is valid in the memory device 102 upon the operation mode (YES in step S306), the code creating unit 414 calculates the ECC on the basis of the data read from the internal circuit 156 (in step S312). The transmitting unit 418 transmits the created ECC 120 to the memory device 102 (in step S314). Further, the transmitting unit 418 transmits the data 118 to the memory device 102 (in step S318).

Even when the ECC processing is invalid upon setting the operation mode (NO in step S306) and when the operation notifying signal is to be outputted (YES in step S316), the first control unit 150 transmits the creating signal 430 to ECC 120 (in step S312), and transmits the ECC 120 to the memory controller 100 (in step S314). The transmitting unit 418 transmits the created ECC 120 to the memory device 102 (in step S314). Furthermore, the transmitting unit 418 transmits the data 118 to the memory device 102 (in step S318). When the operation notifying signal is not outputted (NO in step S316), the transmitting unit 418 transmits the data 118 received from the internal circuit 156 to the memory device 102 (in step S318).

The ECC processing is valid upon setting the operation mode of the memory device 102, thereby enabling the ECC processing by the memory device 102 irrespective of the operation notifying signal. Accordingly, the operation notifying signal is not required and the data reading processing speed from the memory device 102 may be improved. Further, even when the ECC processing is invalid upon setting the operation mode, the operation notifying signal is outputted, thereby executing the ECC processing of specific data in the memory device 102.

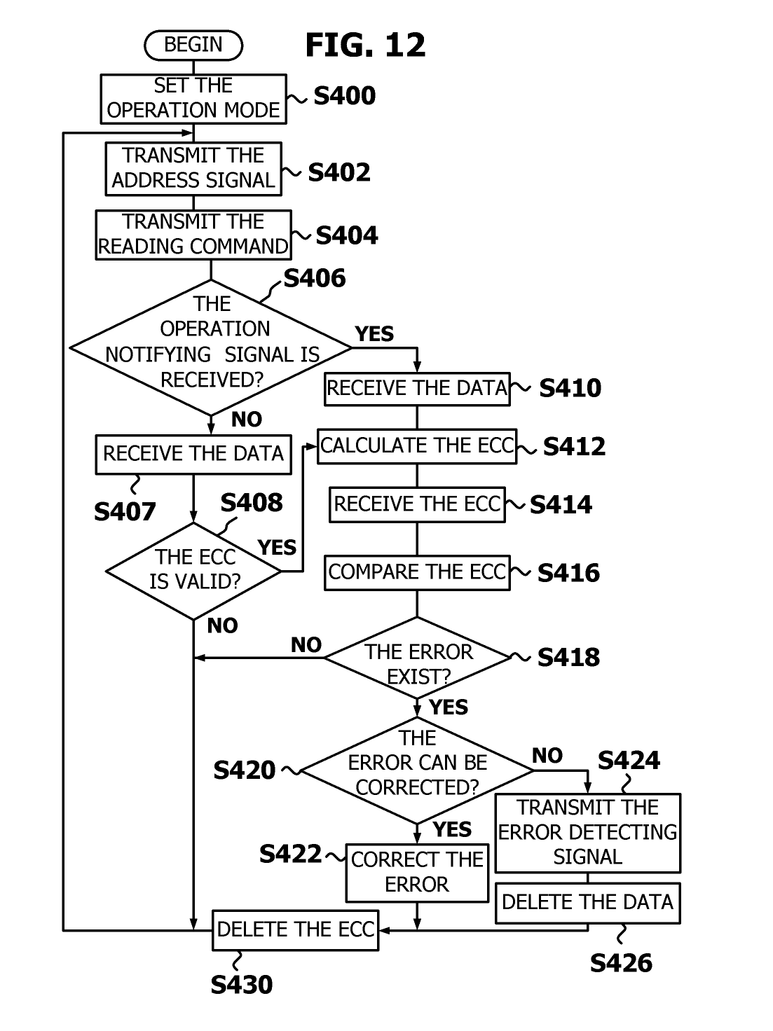

FIG. 12 is an operational flowchart of the memory controller 100 for explaining data reading processing from the memory device 102 to the memory controller 100. The first control unit 150 in the memory controller 100 transmits the command signal 112 that sets the operation mode for determining whether or not the ECC processing is valid to the memory device 102 (in step S400). The first control unit 150 transmits the address signal 114 for designating the address of the memory device 102 for storing the data to be read (in step S402). The first control unit 150 transmits a reading command to the memory device 102 in response to the command signal 112, thereby setting the memory device 102 to a reading mode (in step S404).

When the operation notifying signal is received (YES in step S406), the receiving unit 400 receives the data and transmits the request signal 432 indicating that the ECC processing is performed to the first control unit 150 (in step S410). The error correcting unit 404 calculates the ECC on the basis of the received data (in step S412). The receiving unit 400 receives the ECC data, and transmits the received ECC data to the error correcting unit 404 (in step S414). The error correcting unit 404 compares the ECC created on the basis of the received data with the received ECC and performs the error detecting processing (in step S416).

When the error exists as a result of the error detecting processing (YES in step S418) and when the error can be corrected (YES in step S420), the error correcting unit 404 performs the error correcting processing of the data, and transmits the data after the error correction to the internal circuit 156 (in step S422). After correcting the error, the error correcting unit 404 deletes the ECC (in step S430). The first control unit 150 enters a standby mode until transmitting a next reading command.

When the error exists as a result of the error detecting processing (YES in step S418) and when the error may not be corrected (NO in step S420), the error correcting unit 404 transmits the error detecting signal to the first control unit 150 (in step S424). Accordingly, the first control unit 150 may confirm that the error can not be corrected. In this case, the first control unit 150 may transmit again a reading command to the memory device 102. The error correcting unit 404 deletes the data whose error is not corrected (in step S426). Further, the error correcting unit 404 deletes the received ECC (in step S430).

When the error does not exist as a result of the error detecting processing (NO in step S418), the error correcting unit 404 deletes the ECC and transmits the data to the internal circuit 156 (in step S430).

When the operation notifying signal is not received (NO in step S406), the receiving unit 400 receives the data (in step S407). When the ECC processing is valid upon setting the operation mode (YES in step S408), the error correcting unit 404 calculates the ECC (in step S412).

The ECC processing is valid upon setting the operation mode of the memory device 102. Accordingly, the memory device 102 may perform the ECC processing, irrespective of the operation notifying signal. As a consequence thereof, the operation notifying signal is not required and data writing processing speed may be improved. Further, even when the ECC processing is invalid upon setting the operation mode, the memory device 102 uses the operation notifying signal, thereby enabling the memory controller 100 to execute the ECC processing of only specific data. When the ECC processing is invalid upon setting the operation mode (NO in step S408), the error correcting unit 404 transmits the received data to the internal circuit 156 without the ECC processing.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present inventions have been described in detail, it should be understood that the various changes, substitutions, and alterations could be made hereto without departing from the spirit and scope of the invention.

What is claimed is:

1. A memory device comprising:
a data port for receiving data;
a storing unit for storing data;
a control signal input port for receiving a command signal;
an error correcting unit for performing error correction operation over the data for the data port and the command signal for the control signal input port; and
a control unit for controlling the storing unit for storing the data produced by the error correcting unit.

2. The memory device of claim 1, wherein the error correcting unit deletes the error correcting code stored temporarily in the error correcting unit after correcting error of the data.

3. The memory device of claim 1, wherein the control signal input port receives the command signal for notifying data receiving timing which is different from timing of receiving the error correcting code.

4. The memory device of claim 1, wherein the control signal input port receives the error correcting code as the command signal.

5. The memory device of claim 1, wherein the error correcting unit compares the received error correcting code and an reference error correcting code which is created from the received data.

6. The memory device of claim 5, further comprising a creating unit for outputting condition of the data,
wherein the error correcting unit outputs an error detecting signal to the control unit when the error correcting unit detects a difference between the reference error correcting code and the error correcting code, and
the control unit outputs an condition of the data when the control unit receives the error detecting signal.

7. The memory device of claim 1, the error correcting unit makes error correcting process valid in accordance with received operation notifying signal.

8. The memory device of claim 1, further comprising a code creating unit for creating an error correcting code to correct error of the data when the data is read.

9. An information processing system comprising:
a memory controller for outputting data, an error correcting code of the data, and an command signal; and
a memory device comprising:
a data port for receiving data;
a storing unit for storing data;
a control signal input port for receiving the command signal;
an error correcting unit for performing error correction operation over the data for the data port and the command signal for the control signal input port; and
a control unit for controlling the storing unit for storing the data produced by the error correcting unit.
